(19) United States
(12) Patent Application Publication
(10) Pub. No.: US 2014/0063990 A1
(43) Pub. Date: Mar. 6, 2014

(54) MULTI-CHIP SEMICONDUCTOR APPARATUS

(71) Applicant: SK HYNIX INC., Icheon-si (KR)

(72) Inventors: Young Jun KU, Icheon-si (KR); Tae Sik YUN, Icheon-si (KR)

(73) Assignee: SK HYNIX INC., Icheon-si (KR)

(21) Appl. No.: 13/720,741

(22) Filed: Dec. 19, 2012

(30) Foreign Application Priority Data
Aug. 30, 2012 (KR) 10-2012-0095543

(51) Int. Cl. G11C 7/10

(52) U.S. Cl. CPC G11C 7/1051
USPC 365/189.17

(57) ABSTRACT

A multi-chip semiconductor apparatus includes a plurality of semiconductor chips which are electrically connected through a plurality of through-chip vias (TSVs) and stacked, wherein each of the semiconductor chips includes: a first data input/output line configured to transmit data for a first memory bank; a second data input/output line configured to transmit data for a second memory bank; and a data transmitting/receiving (TX/RX) unit configured to electrically connect any one of the first and second data input/output lines to a first TSV in response to selected memory bank information, during read and write operations for the corresponding semiconductor chip.

### CROSS-REFERENCES TO RELATED APPLICATION

The present application claims priority under 35 U.S.C. §119(a) to Korean application number 10-2012-0095543 filed on Aug. 30, 2012 in the Korean Intellectual Property Office, which is incorporated herein by reference in its entirety.

### BACKGROUND

1. Technical Field

The present invention generally relates to a semiconductor apparatus, and more particularly, to signal transmission and reception of a multi-chip semiconductor apparatus.

2. Related Art

A packaging technology for the semiconductor apparatus has continuously developed to satisfy the miniaturization and mounting reliability. For example, the demand for miniaturization has accelerated the technology development for a package close to a chip size, and the demand for mounting reliability has brought the importance of a packaging technology capable of improving the efficiency of mounting operation and the mechanical/electrical reliability after mounting.

Furthermore, as high performance of electric and electronic products is required with the miniaturization thereof, various technologies for providing a high-capacity semiconductor module have been researched and developed. In order to provide a high-capacity semiconductor module, high integration for a memory chip may be applied. The high integration may be realized by integrating a large number of cells into a limited space of a semiconductor chip.

However, the high integration for a memory chip requires a high-level technology and a large amount of development time. For example, a fine critical dimension (CD) may be required. Therefore, a stack technology has been proposed as another method for providing a high-capacity semiconductor module.

A stacked multi-chip semiconductor apparatus includes two or more semiconductor chips stacked in one package. In order to stack a plurality of semiconductor chips in a package, a structure using through-silicon vias (TSVs) may be applied. In the package using TSVs, holes are formed through the semiconductor chips, and filled with a conductive material to form the TSVs. Through the TSVs, upper and lower semiconductor chips are electrically connected.

FIG. 1 is a diagram illustrating a conventional multi-chip semiconductor apparatus including a plurality of semiconductor chips stacked and connected through TSVs.

The multi-chip semiconductor apparatus illustrated in FIG. 1 includes a plurality of semiconductor chips 10 and 20A to 20D. The multi-chip semiconductor apparatus communicates with an external processor (not illustrated) through a pad PAD formed in the chip 10 positioned at the lowermost part among the semiconductor chips. The plurality of semiconductor chips are electrically connected through the TSVs such that the processor may control the semiconductor chips. Each of the TSVs may transmit and receive various signals and data to the respective chips, and is used as a unit to supply power required for the respective chips.

FIG. 1 illustrates that the plurality of semiconductor chips include the master chip 10 and the plurality of slave chips 20A to 20D (i.e., SLAVE CHIP1 to SLAVE CHIP4). In general, the master chip 10 is configured to exchange signals with the external processor and control the slave chips 20A to 20D. Furthermore, the respective slave chips 20A to 20D are configured to perform a specific operation according to the control of the master chip 10. For example, the master chip 10 includes peripheral circuits related to signal input/output and control signals, and the slave chips 20A to 20D include memory banks for storing data.

FIG. 2 generally is a block diagram illustrating an embodiment of the slave chips 20A to 20D. Since the respective slave chips have the same configuration, the configuration of the first slave chip 20A will be representatively described.

The slave chip 20A includes a plurality of memory banks 21_0A to 21_7A to store data in memory cells. Furthermore, the slave chip 20A includes a plurality of data input/output lines GIO_{—0<}0:63> to GIO_{—7<}0:63> and a plurality of TSV sets 23_0A to 23_7A, in order to perform data transmission between the master chip 10 and the respective memory banks 21_0A to 21_7A during a data input/output mode. For example, when each of the memory banks 21_0A to 21_7A inputs/outputs 64 data at the same time, each of the data input/output lines GIO_{—0<}0:63> to GIO_{—0<}0:63> includes 64 input/output lines, and each of the TSV sets 23_0A to 23_7A also includes 64 TSVs.

Specifically, the operation of transmitting and receiving data to and from the slave chip 20A is performed as follows. First, during data transmission, data stored in the respective memory banks 21_0A to 21_7A are transmitted to the data input/output lines GIO_{—0<}0:63> to GIO_{—7<}0:63> connected to the respective memory banks. The data are transmitted to the master chip 10 through the TSV sets 23_0A to 23_7A connected to the respective data input/output lines GIO_{—0<}0:63> to GIO_{—0<}0:63>. During data reception, data transmitted from the master chip 10 are transmitted to the slave chip 20A through the TSV sets 23_0A to 23_7A. The data are transmitted to the corresponding memory banks 21_0A to 21_7A through the respective data input/output lines GIO_{—0<}0:63> to GIO_{—0<}0:63>.

In general, since TSVs formed in a semiconductor chip occupy a very large area, it is very important to reduce the number of TSVs as much as possible and efficiently arrange the TSVs, in order to increase the chip efficiency.

Therefore, research is being conducted on various methods for reducing the number of TSVs required for the salve chip 20A to transmit and receive data, thereby increasing the area efficiency.

### SUMMARY

In an embodiment, a multi-chip semiconductor apparatus includes a plurality of semiconductor chips which are electrically connected through a plurality of through-chip vias (TSVs) and stacked, wherein each of the semiconductor chips includes: a first data input/output line configured to transmit data for a first memory bank; a second data input/output line configured to transmit data for a second memory bank; and a data transmitting/receiving (TX/RX) unit configured to electrically connect any one of the first and second data input/output lines to a first TSV in response to selected memory bank information, during read and write operations for the corresponding semiconductor chip.

In an embodiment, a multi-chip semiconductor apparatus includes a plurality of semiconductor chips which are electrically connected through a plurality of TSVs and stacked, wherein each of the semiconductor chips includes: a first data input/output line configured to commonly manage data transmission of first and second memory banks; a second data input/output line configured to commonly manage data transmission of third and fourth memory banks; and a data TX/RX unit configured to electrically connect any one of the first and second data input/output lines to the first TSV in response to the selected memory bank information, during read and write operations for the corresponding memory chip.

In an embodiment, a multi-chip semiconductor apparatus includes: a plurality of slave chips each including first and second memory banks; and a master chip configured to control operations of the plurality of slave chips, wherein the master chip and the plurality of slave chips are electrically connected through a plurality of TSVs and stacked, and each of the slave chips includes: a first data input/output line configured to transmit data for a first memory bank; a second data input/output line configured to transmit data for a second memory bank; and a data TX/RX unit configured to electrically connects any one of the first and second data input/output lines to the first TSV in response to selected memory bank information, during read and write operations for the corresponding slave chip.

### BRIEF DESCRIPTION OF THE DRAWINGS

Features, aspects, and embodiments are described in conjunction with the attached drawings, in which:

FIG. 1 is a diagram illustrating a conventional multi-chip semiconductor apparatus;

FIG. 2 is a block diagram illustrating a an embodiment of a slave chip of FIG. 1;

FIG. 3 is a block diagram illustrating a slave chip according to an embodiment;

FIG. 4 is a block diagram of a multi-chip semiconductor apparatus according to an embodiment;

FIG. 5 is a waveform diagram during a read operation of the multi-chip semiconductor apparatus of FIG. 4;

FIG. 6 is a waveform diagram during a write operation of the multi-chip semiconductor apparatus of FIG. 4;

FIG. 7 is a block diagram illustrating an embodiment of a data TX/RX unit of FIG. 4;

FIG. 8 is a circuit diagram illustrating an embodiment of a TX unit of FIG. 7;

FIG. 9 is a circuit diagram illustrating an embodiment of an RX unit of FIG. 7; and

FIG. 10 is a block diagram illustrating a slave chip according to an embodiment.

### DETAILED DESCRIPTION

Hereinafter, a multi-chip semiconductor apparatus according to the various embodiments will be described below with reference to the accompanying drawings through the embodiments.

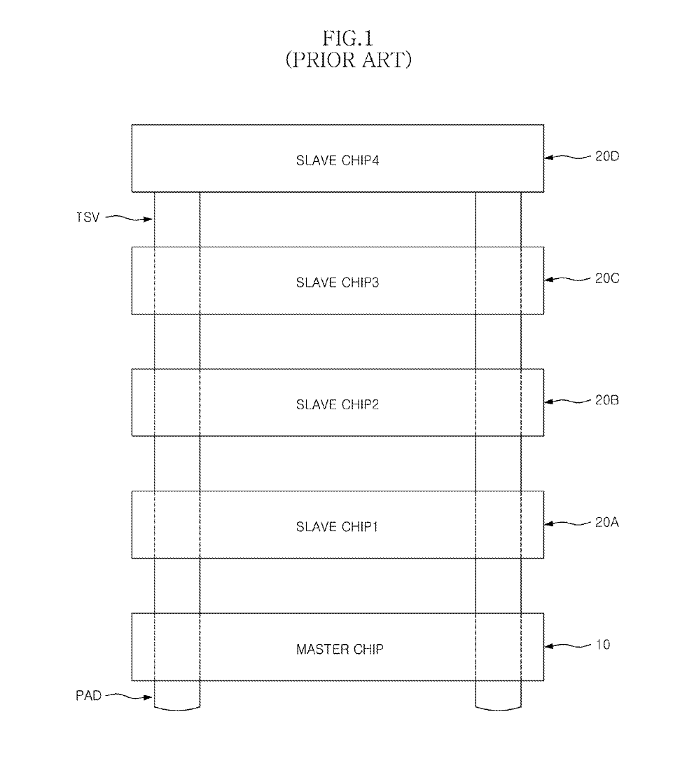

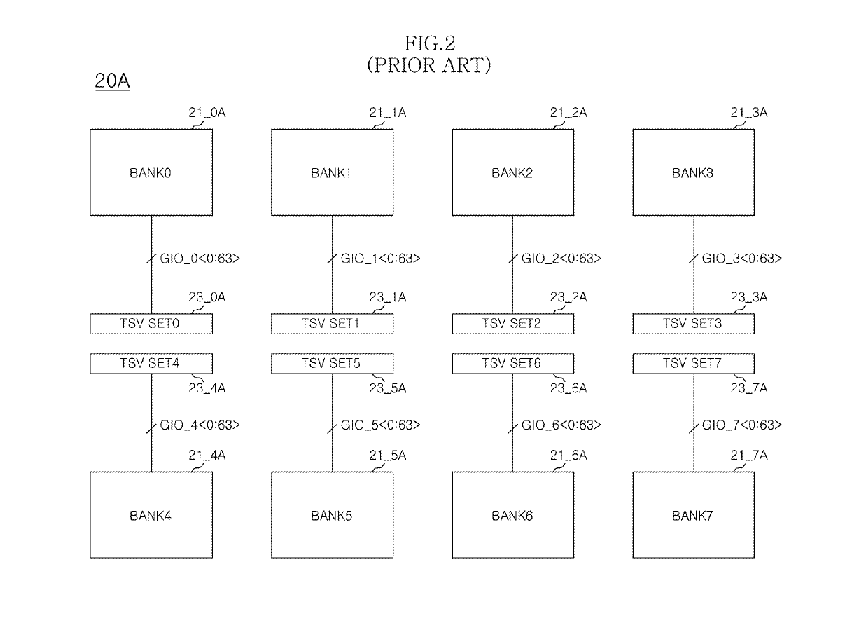

Embodiments relate to a multi-chip semiconductor apparatus including a plurality of semiconductor chips which are electrically connected through TSVs and stacked as illustrated in FIG. 1. The multi-chip semiconductor apparatus may include a master chip and a plurality of slave chips controlled by the master chip.

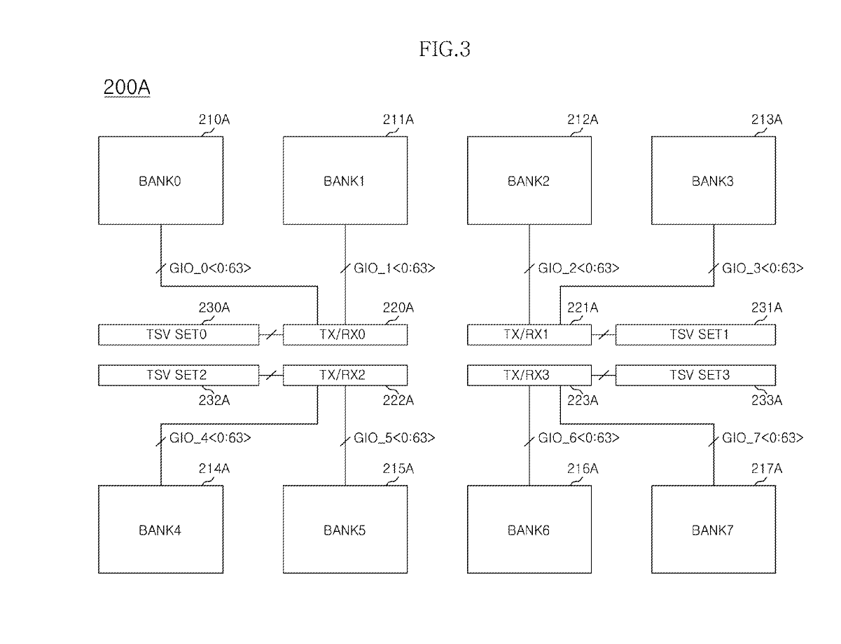

FIG. 3 is a block diagram illustrating a slave chip 200A according to an embodiment.

The slave chip 200A may include a plurality of memory banks 210A to 217A to store data in memory cells. FIG. 3 illustrates first to eighth memory banks 210A to 217A, but various embodiments not limited thereto. The slave chip 200A may include a necessary number of memory banks, for example, two or more memory banks.

The slave chip 200A may include first to eighth data input/output lines GIO_{—0<}0:63> to GIO_{—7<}0:63>, first to fourth data transmitting/receiving (TX/RX) units 220A to 223A, and first to fourth TSV sets 230A to 233A, in order to perform data transmission between the master chip and the respective memory chips 210A to 217A in a data input/output mode.

The first to eighth data input/output lines GIO_{—0<}0:63> to GIO_{—7<}0:63> are configured to transmit data of the first to eighth memory banks 210A to 217A, respectively. For example, when each of the memory banks 210A to 217A can input/output 64 data at the same time, each of the first to eighth data input/output lines GIO_{—0<}0:63> to GIO_{—7<}0:63> may include 64 input/output lines.

The first to fourth data TX/RX units 220A to 223A serve to connect the data input/output lines GIO_{—0<}0:63> to GIO_{—7<}0:63> to the TSV sets 230A to 233A. According to an embodiment, two or more data input/output lines share one TSV set. Each of the data TX/RX units 220A to 223A serves to electrically connect a data input/output line corresponding to selected memory bank information, among two or more data input/output lines sharing one TSV set, to the TSV set during a data input/output mode for the corresponding slave chip 200A. Specifically, during a read operation for the corresponding slave chip 200A, each of the data TX/RX units 220A to 223a transmits read data to the TSV set from the data input/output line corresponding to the selected memory bank information among the two or more data input/output lines sharing one TSV set. On the other hand, during a write operation for the corresponding slave chip 200A, each of the data TX/RX units 220A to 223a transmits write data transmitted to the corresponding slave chip 200A through a TSV set to the data input/output line corresponding to the selected memory bank information among two or more data input/output line sharing the TSV set.

FIG. 3 illustrates that each of the data TX/RX units 220A to 223A selectively connects any one of two data input/output lines to one TSV set. The first data TX/RX unit 220A may be configured to selectively connect the first and second data input/output lines GIO_{—0<}0:63> and GIO_{—1<}0:63> to the first TSV set 230A. The second data TX/RX unit 221A may be configured to selectively connect the third and fourth data input/output lines GIO_{—2<}0:63> and GIO_{—3<}0:63> to the second TSV set 231A. The third data TX/RX unit 222A may be configured to selectively connect the fifth and sixth data input/output lines GIO_{—4<}0:63> and GIO_{—5<}0:63> to the third TSV set 232A. The fourth data TX/RX unit 223A may be configured to selectively connect the seventh and eighth data input/output lines GIO_{—6<}0:63> and GIO_{—7<}0:63> to the fourth TSV set 233A.

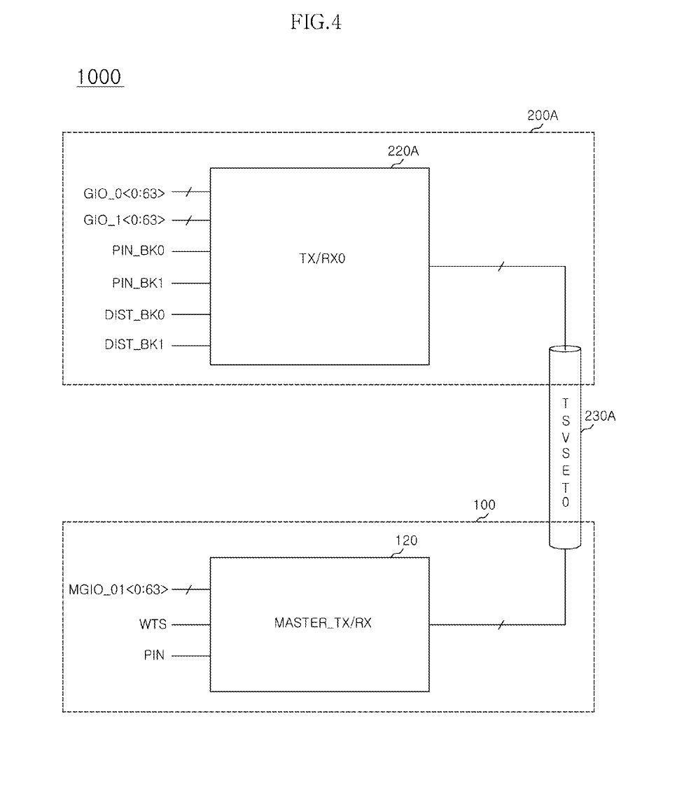

FIG. 4 is a block diagram of the multi-chip semiconductor apparatus 1000 according to an embodiment.

The multi-chip semiconductor apparatus 1000 may include a master chip 100 and a plurality of slave chips. FIG. 4 illustrates only the first slave chip 200A among the plurality of slave chips. FIG. 4 briefly illustrates the specific configuration of the master chip 100 and the slave chip 200A, or particularly, only the configuration for data transmission/reception.

The slave chip 200A may include a first data TX/RX unit 220A and a first TSV set 230A. As described with reference to FIG. 3, the slave chip 200A may include a plurality of data TX/RX units and TSV sets. Referring to FIG. 4, a specific data TX/RX operation through the first data TX/RX unit 220A and the first TSV set 230A will be described. Additionally, the first TSV set 230A electrically connects the slave chip 200A and the master chip 100, and is shared by the slave chip 200A and the master chip 100.

The master chip 100 may include a master TX/RX unit 120 to transmit and receive data to and from the first TSV set 230A, during a data input/output mode for the slave chip 200A.

Specifically, the first data TX/RX unit 220A transmits read data transmitted from the first or second data input/output line GIO_{—0<}0:63> or GIO_{—1<}0:63> to the first TSV set 230A in response to first and second memory bank pin signals PIN_BK0 and PIN_BK1, during a read operation. At this time, the first and second memory bank pin signals PIN_BK0 and PIN_BK1 are signals which are activated at a predetermined time after a chip select signal (not illustrated) for the slave chip 200A is activated, a read command (not illustrated) is applied to the slave chip 200A, and a first or second memory bank select signal (not illustrated) is activated. That is, the first and second memory bank pin signals PIN_BK0 and PIN_BK1 are activated at a time point when the data read from the first or second memory bank is transmitted to the outside.

The master TX/RX unit 120 receives the read data transmitted from the first TSV set 230A through a master input/output line MGIO_01<0:63> in response to a pin signal PIN, during the read operation. The pin signal PIN is a signal which is activated when the first or second memory bank pin signal PIN_BK0 or PIN_BK1 is activated in case where the multi-chip semiconductor apparatus 100 performs a read operation.

FIG. 5 is a waveform diagram of the first and second memory bank pin signals PIN_BK0 and PIN_BK1 and the pin signal PIN. During a read operation for the corresponding slave chip 200A, the first memory bank pin signal PIN_BK0 is activated at a predetermined time after the first memory bank is selected (i.e., R0), and the second memory bank pin signal PIN_BK1 is activated in a predetermined time after the second memory bank is selected (i.e., R1). Furthermore, during a read operation for each bank, the pin signal PIN is activated.

The master TX/RX unit 120 transmits the write data loaded in the master input/output line MGIO_01<0:63> to the first TSV set 230A in response to a write strobe signal WTS which is activated during a write operation.

The data TX/RX unit 220A transmits the write data transmitted through the first TSV set 230A to the first or second data input/output line GIO_{—0<}0:63> or GIO_{—1<}0:63> in response to first and second memory bank write strobe signals DIST_BK0 and DIST_BK1 during the write operation. At this time, the first and second memory bank write strobe signals DIST_BK0 and DIST_BK1 are signals which are activated at a predetermined time after a chip select signal (not illustrated) for the slave chip 200A is activated, a write command (not illustrated) is applied to the slave chip 200A, and a first or second memory bank select signal (not illustrated) is activated.

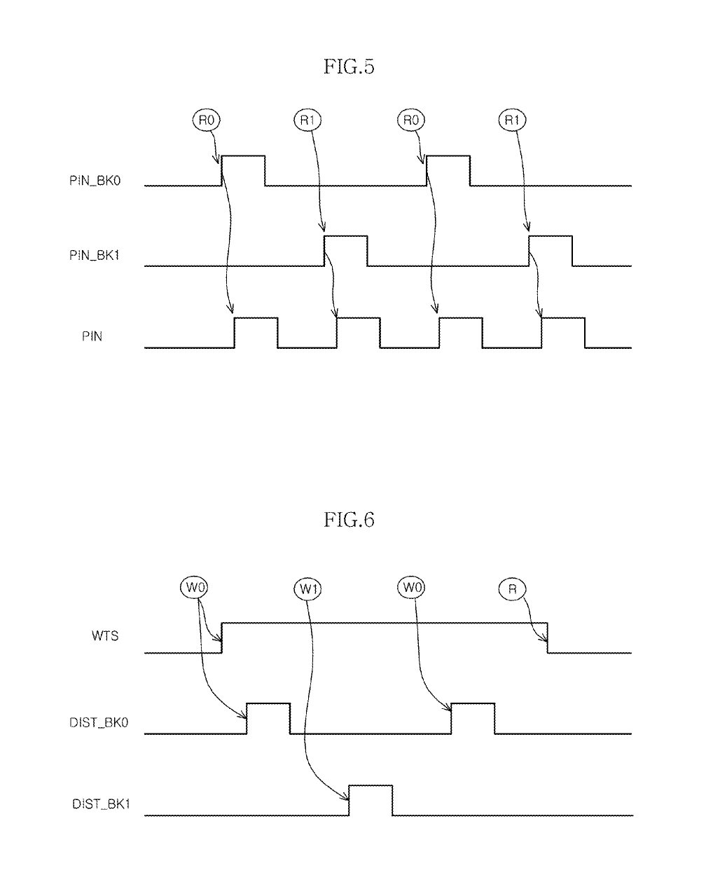

FIG. 6 is a waveform diagram of the write strobe signal WTS and the first and second memory bank write strobe signals DIST_BK0 and DIST_BK1. First, when a write command (i.e., W0) is applied to the master chip 100 from outside, the write strobe signal WTS is activated. The activated write strobe signal WTS may be then deactivated when a read command (i.e., R) is applied. When a write command for the slave chip 200A is applied, the first memory bank write strobe signal DIST_BK0 is activated in a predetermined time after the first memory bank is selected (i.e., W0), and the second memory bank write strobe signal DIST_BK1 is activated in a predetermined time after the second memory bank is selected (i.e., W1).

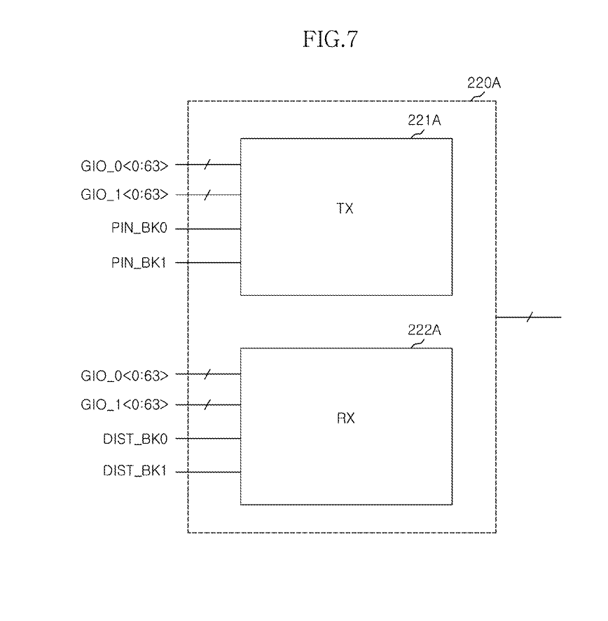

FIG. 7 is a block diagram illustrating an embodiment of the data TX/RX unit 220A.

The data TX/RX unit 220A may include a TX unit 221A to transmit read data and an RX unit 222A to receive write data.

The TX unit 221A may be configured to transmit read data transmitted from the first data input/output line GIO_{—0<}0:63> to the first TSV set 230A in response to the first memory bank pin signal PIN_BK0, and transmit read data transmitted from the second data input/output line GIO_{—1<}0:63> to the first TSV set 230A in response to the second memory bank pin signal PIN_BK1.

The RX unit 222A may be configured to receive write data transmitted through the first TSV set 230A through the first data input/output line GIO_{—0<}0:63> in response to the first memory bank write strobe signal DIST_BK0, and receive the write data transmitted through the first TSV set 230A through the second data input/output line GIO_{—1<}0:63> in response to the second memory bank write strobe signal DIST_BK1.

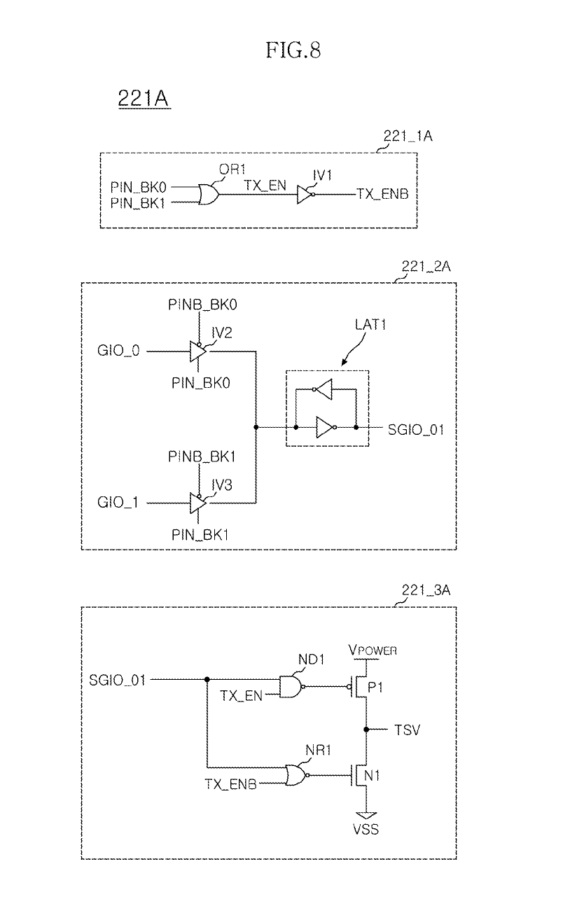

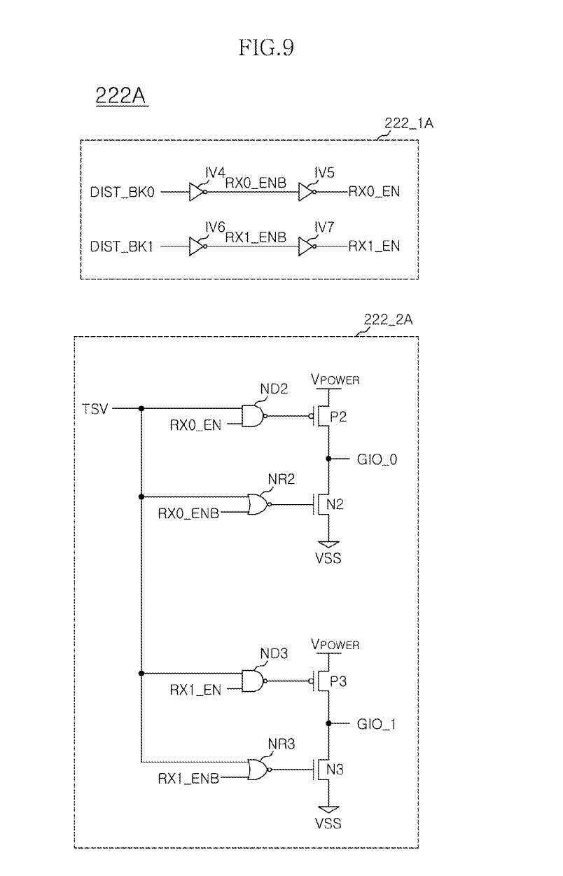

FIG. 8 is a circuit diagram illustrating an embodiment of the TX unit 221A.

The TX unit 221 may include a TX enable signal generation section 221_1A, an input/output line synthesis section 221_2A, and a data output driving section 221_3A.

The TX enable signal generation section 221_1A may be configured to generate a TX enable signal TX_EN which is activated when any one of the first and second memory bank pin signals PIN_BK0 and PIN_BK1 is activated. Furthermore, the TX enable signal generation section 221_1A may be configured to invert the TX enable signal TX_EN and generate the inverted TX enable signal TX_ENB.

Specifically, the TX enable signal generation 221_1A may include a first OR gate OR1 and a first inverter IV1. The first OR gate OR1 may be configured to receive the first and second memory bank pin signals PIN_BK0 and PIN_BK1 and generate the TX enable signal TX_EN. The first inverter IV1 may be configured to invert the TX enable signal TX_EN and generate the inverted TX enable signal TX_ENB.

The input/output line synthesis section 221_2A may be configured to transmit read data transmitted from the first and second data input/output lines GIO_0 and GIO_1 to a synthesis input/output line SGIO_01 in response to the first and second memory bank pin signal PIN_BK0 and PIN_BK1, respectively. FIG. 8 illustrates that the first and second data input/output lines GIO_0 and GIO_1 of one of the first and second data input/output lines GIO_{—0<}0:63> and GIO_{—1<}0:63> are synthesized.

Specifically, the input/output line synthesis section 221_2A may include second and third inverters IV2 and IV3 and a first latch LAT1. The second inverter IV2 may be configured to transmit read data loaded in the first data input/output line GIO_0 in response to the first memory bank pin signal PIN_BK0 and the inverted first memory bank pin signal PINB_BK0. The third inverter IV3 may be configured to transmit read data loaded in the second data input/output line GIO_1 in response to the second memory bank pin signal PIN_BK1 and the inverted second memory bank pin signal PINB_BK1. The first latch LAT1 may be configured to latch the read data transmitted from the second or third inverter IV2 or IV3 and transmit the latched data to the synthesis input/output line SGIO_01.

The data output driving section 221_3A may be configured to drive output data to a corresponding TSV of the first TSV set 230A in response to the level of the read data loaded in the synthesis input/output line SGIO_01, when the TX enable signal TX_EN is activated.

Specifically, the data output driving section 221_3A may include a first NAND gate ND1, a first PMOS transistor P1, a first NOR gate NR1, and a first NMOS transistor N1. The first NAND gate ND1 may be configured to receive the TX enable signal TX_EN and the read data loaded in the synthesis input/output line SGIO_01. The first NOR gate NR1 may be configured to receive the inverted TX enable signal TX_ENB and the read data loaded in the synthesis input/output line SGIO_01. The first PMOS transistor P1 may be configured to drive output data to the TSV from a power supply voltage VPOWER in response to an output signal of the first NAND gate ND1. The NMOS transistor N1 may be configured to discharge a voltage level driven to the TSV to a ground voltage VSS in response to an output signal of the first NOR gate NR1.

FIG. 9 is a circuit diagram illustrating an embodiment of the RX unit 222A.

The RX unit 222A may include an RX enable signal generation section 222_1A and a data input driving section 222_2A.

The RX enable signal generation section 222_1A may be configured to generate an activated first RX enable signal RX0_EN in response to the activated first memory bank write strobe signal DIST_BK0, and generate an activated second RX enable signal RX1_EN in response to the activated second memory bank write strobe signal DIST_BK1.

Specifically, the RX enable signal generation section 222_1A may include fourth to seventh inverters IV4 to IV7. The fourth inverter IV4 may be configured to receive the first memory bank write strobe signal DIST_BK0 and output the inverted first RX enable signal RX0_ENB. The fifth inverter IV5 may be configured to receive the inverted first RX enable signal RX0_ENB and output the first RX enable signal RX0_EN. The sixth inverter IV6 may be configured to receive the second memory bank write strobe signal DIST_BK1 and output the inverted second RX enable signal RX1_ENB. The seventh inverter IV7 may be configured to receive the inverted second RX enable signal RX1_ENB and output the second RX enable signal RX1_EN.

The data input driving section 222_2A may be configured to drive the level of write data transmitted through a TSV included in the first TSV set 230A to the first data input/output line GIO_0 when the first RX enable signal RX0_EN is activated, and drive the level of the write data transmitted through the TSV to the second data input/output line GIO_1 when the second RX enable signal RX1_EN is activated.

Specifically, the data input driving section 222_2A may include second and third NAND gates ND2 and ND3, second and third NOR gates NR2 and NR3, second and third PMOS transistors P2 and P3, and second and third NMOS transistors N2 and N3.

The second NAND gate ND2 may be configured to receive write data transmitted through the TSV and the first RX enable signal RX0_EN. The second NOR gate NR2 may be configured to receive write data transmitted through the TSV and the inverted first RX enable signal RX0_ENB. The second PMOS transistor P2 may be configured to drive input data to the first data input/output line GIO_0 from the power supply voltage VPOWER in response to an output signal of the second NAND gate ND2. The second NMOS transistor N2 may be configured to discharge the voltage level driven to the first data input/output line GIO_0 to the ground voltage VSS in response to an output signal of the second NOR gate NR2.

The third NAND gate ND3 may be configured to receive write data transmitted through the TSV and the second RX enable signal RX1_EN. The third NOR gate NR3 may be configured to receive write data transmitted through the TSV and the inverted second RX enable signal RX1_ENB. The third PMOS transistor P3 may be configured to drive input data to the second data input/output line GIO_1 from the power supply voltage VPOWER in response to an output signal of the third NAND gate ND3. The third NMOS transistor N3 may be configured to discharge the voltage level driven to the second data input/output line GIO_1 to the ground voltage VSS in response to an output signal of the third NOR gate NR3.

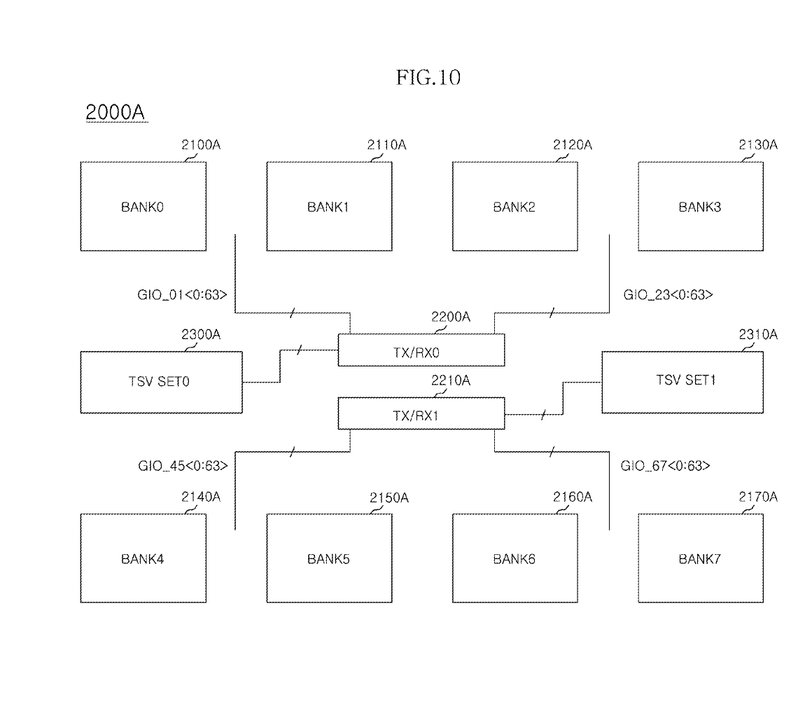

FIG. 10 is a block diagram illustrating a slave chip 2000A according to an embodiment.

The configuration of the slave chip 2000A illustrated in FIG. 10 is similar to the configuration of the slave chip 200A illustrated in FIG. 3. That is, the slave chip 2000A illustrated in FIG. 10 may be configured in such a manner that a plurality of data input/output lines share one TSV set.

In addition, however, the slave chip 2000A may be configured in such a manner that a plurality of memory banks share one data input/output line. Therefore, the number of TSV sets used for the entire slave chip 2000A may be reduced, compared to the slave chip 200A illustrated in FIG. 3.

Specifically, the slave chip 2000A may include a plurality of memory banks 2100A to 2170A. FIG. 10 illustrates first to eighth memory banks 2100A to 2170A, but the present invention is not limited thereto. The slave chip 2000A may include a necessary number of memory banks, for example, two or more memory banks.

The slave chip 2000A may include first to fourth data input/output lines GIO_01<0:63> to GIO_{—67<}0:63>, first and second data TX/RX units 2200A and 2210A, and first and second TSV sets 2300A and 2310A, in order to perform data transmission between a master chip and the respective memory banks 2100A to 2170A during a data input/output mode.

The first to fourth data input/output lines GIO_01<0:63> to GIO_{—67<}0:63> serve to transmit data of the memory banks. According to an embodiment, however, a plurality of memory banks share one data input/output line. FIG. 10 illustrates that two memory banks share one data input/output line, but the embodiments not limited thereto. The first data input/output line GIO_01<0:63> may be shared by the first and second memory banks 2100A and 2110A. The second data input/output line GIO_{—23<}0:63> may be shared by the third and fourth memory banks 2120A and 2130A. The third data input/output line GIO_{—45<}0:63> may be shared by the fifth and sixth memory banks 2140A and 2150A. The fourth data input/output line GIO_{—67<}0:67> may be shared by the seventh and eighth memory banks 2160A and 2170A. At this time, when two memory banks share one data input/output line, the data of the corresponding memory banks are selectively driven to the input/output line in response to a bank select signal. This configuration will be easily understood by those skilled in the art, and thus the detailed descriptions thereof are omitted herein.

The first and second data TX/RX units 2200A and 2210A serve to connect the data input/output lines GIO_01<0:63> to GIO_{—67<}0:63> to the TSV sets 2300A and 2310A. According to an embodiment, two or more data input/output lines share one TSV set. Each of the data TX/RX units 2200A and 2210A serves to electrically connect a data input/output line, corresponding to selected memory bank information among two or more data input/output lines sharing the TSV set, to a TSV set during an input/output mode for the corresponding slave chip 2000A. Specifically, during a read operation for the slave chip 2000A, each of the data TX/RX units 2200A and 2210A transmits read data to the TSV set from the data input/output line corresponding to the selected memory bank information among the two or more data input/output lines sharing the TSV set. On the other hand, during a write operation for the slave chip 2000A, each of the data TX/RX units 2200A and 2210A transmits write data transmitted to the salve chip 2000A through a TSV set to a data input/output line corresponding to selected memory bank information among two or more data input/output lines sharing the TSV set.

FIG. 10 illustrates that each of the data TX/RX units 2200A and 2210A selectively connects any one of two data input/output lines to one TSV set. The first data TX/RX units 2200A selectively connects the first and second data input/output lines GIO_01<0:63> and GIO_{—23<}0:63> to the first TSV set 2300A. The second data TX/RX unit 2210A selectively connects the third and fourth data input/output lines GIO_{—45<}0:64> and GIO_{—67<}0:64> to the second TSV set 2310A.

The specific configuration and operation of the data TX/RX units 2200A and 2210A are the same as those of the slave chip 200A illustrated in FIG. 3.

While various embodiments have been described above, it will be understood to those skilled in the art that the embodiments described are by way of example only. Accordingly, the multi-chip semiconductor apparatus described herein should not be limited based on the described embodiments.

What is claimed is:

1. A multi-chip semiconductor apparatus comprising a plurality of semiconductor chips which are electrically connected through a plurality of through-chip vias (TSVs) and stacked,
wherein each of the semiconductor chips comprises:
a first data input/output line configured to transmit data for a first memory bank;
a second data input/output line configured to transmit data for a second memory bank; and
a data transmitting/receiving (TX/RX) unit configured to electrically connect any one of the first and second data input/output lines to a first TSV in response to selected memory bank information, during read and write operations for the corresponding semiconductor chip.

2. The multi-chip semiconductor apparatus according to claim 1, wherein the data TX/RX unit transmits read data transmitted from any one of the first and second data input/output lines to the first TSV in response to the selected memory bank information, during the read operation for the corresponding semiconductor chip.

3. The multi-chip semiconductor apparatus according to claim 1, wherein the data TX/RX unit receives write data transmitted from the first TSV through any one of the first and second data input/output lines in response to the selected memory bank information, during the write operation for the corresponding semiconductor chip.

4. A multi-chip semiconductor apparatus comprising a plurality of semiconductor chips which are electrically connected through a plurality of TSVs and stacked,
wherein each of the semiconductor chips comprises:
a first data input/output line configured to commonly manage data transmission of first and second memory banks;
a second data input/output line configured to commonly manage data transmission of third and fourth memory banks; and
a data TX/RX unit configured to electrically connect any one of the first and second data input/output lines to the first TSV in response to the selected memory bank information, during read and write operations for the corresponding memory chip.

5. The multi-chip semiconductor apparatus according to claim 4, wherein the first data input/output line transmits data of the first or second memory bank in response to the selected memory bank information.

6. The multi-chip semiconductor apparatus according to claim 4, wherein the second data input/output line transmits data of the third or fourth memory bank in response to the selected memory bank information.

7. The multi-chip semiconductor apparatus according to claim 4, wherein the data TX/RX unit transmits read data transmitted from any one of the first and second data input/output lines to the first TSV in response to the selected memory bank information, during the read operation for the corresponding semiconductor chip.

8. The multi-chip semiconductor apparatus according to claim 4, wherein the data TX/RX unit receives write data transmitted from the first TSV through any one of the first and second input/output lines in response to the selected memory bank information, during the write operation for the corresponding semiconductor chip.

9. A multi-chip semiconductor apparatus comprising:
a plurality of slave chips each comprising first and second memory banks; and
a master chip configured to control operations of the plurality of slave chips,
wherein the master chip and the plurality of slave chips are electrically connected through a plurality of TSVs and stacked, and
each of the slave chips comprises:
a first data input/output line configured to transmit data for a first memory bank;
a second data input/output line configured to transmit data for a second memory bank; and
a data TX/RX unit configured to electrically connect any one of the first and second data input/output lines to the first TSV in response to selected memory bank information, during read and write operations for the corresponding slave chip.

10. The multi-chip semiconductor apparatus according to claim 9, wherein the master chip comprises a master TX/RX unit configured to electrically connect the first TSV and a master input/output line, during the read and write operations for the corresponding slave chip.

11. The multi-chip semiconductor apparatus according to claim 10, wherein the data TX/RX unit comprises:
a TX unit configured to transmit read data transmitted from any one of the first and second data input/output lines to the first TSV in response to the selected memory bank information, during the read operation for the corresponding slave chip; and
an RX unit configured to receive write data transmitted from the first TSV through any one of the first and second data input/output lines in response to the selected memory bank information, during the write operation for the corresponding slave chip.

12. The multi-chip semiconductor apparatus according to claim 11, wherein the TX unit transmits read data transmitted from the first data input/output line to the first TSV in response to a first memory bank pin signal, and transmits read data transmitted from the second data input/output line to the first TSV in response to a second memory bank pin signal.

13. The multi-chip semiconductor apparatus according to claim 12, wherein the first memory bank pin signal comprises a signal which is activated at a predetermined time after a chip select signal for the corresponding slave chip is activated, a read command is applied to the slave chip, and a first memory bank select signal is activated, and
the second memory bank pin signal comprises a signal which is activated at a predetermined time after the chip select signal for the corresponding slave chip is activated, the read command is applied to the slave chip, and a second memory bank select signal is activated.

14. The multi-chip semiconductor apparatus according to claim 13, wherein the TX unit comprises:
a TX enable signal generation section configured to generate a TX enable signal which is activated when any one of the first and second memory bank pin signals is activated;
an input/output line synthesis section configured to transmit the read data transmitted from the first or second data input/output line to a synthesis input/output line in response to the activated first and second memory bank pin signals; and
a data output driving section configured to drive output data to the first TSV in response to the level of the read data loaded in the synthesis input/output line, when the TX enable signal is activated.

15. The multi-chip semiconductor apparatus according to claim 14, wherein the master TX unit receives the output data transmitted to the TSV through the master input/output line in response to a pin signal which is activated when the first or second memory bank pin signal is activated.

16. The multi-chip semiconductor apparatus according to claim 11, wherein the master TX/RX unit transmits write data loaded in the master input/output line to the first TSV in response to a write strobe signal which is activated when a write command is applied to the master chip.

17. The multi-chip semiconductor apparatus according to claim 12, wherein the RX unit receives the write data transmitted through the first TSV through the first data input/output line in response to a first memory bank write strobe signal, and receives the write data transmitted through the first TSV through the second data input/output line in response to a second memory bank write strobe signal.

18. The multi-chip semiconductor apparatus according to claim 17, wherein the first memory bank write strobe signal comprises a signal which is activated at a predetermined time after a chip select signal for the corresponding slave chip is activated, a write command is applied to the slave chip, and a first memory bank select signal is activated, and
the second memory bank write strobe signal comprises a signal which is activated at a predetermined time after the chip select signal for the corresponding slave chip is activated, the write command is applied to the salve chip, and a second memory bank select signal is activated.

19. The multi-chip semiconductor apparatus according to claim 18, wherein the RX unit comprises:
an RX enable signal generation section configured to generate an activated first RX enable signal in response to the activated first memory bank write strobe signal, and generate an activated second RX enable signal in response to the activated second memory bank write strobe signal; and
a data input driving section configured to drive input data to the first data input/output line in response to the level of the write data transmitted through the first TSV when the first RX enable signal is activated, and drive input data to the second data input/output line in response to the level of the write data transmitted through the first TSV when the second RX enable signal is activated.

20. The multi-chip semiconductor apparatus according to claim 9, wherein each of the slave chips further comprises third and fourth memory banks,
the first data input/output line commonly manages data transmission of the first and third memory banks, and
the second data input/output line commonly manages data transmission of the second and fourth memory banks.
